(19) United States
(12) Patent Application Publication
(10) Pub. No.: US 2017/0178892 A1
(43) Pub. Date: Jun. 22, 2017

(54) SUBSTRATE PROCESSING APPARATUS AND SUBSTRATE PROCESSING METHOD

(71) Applicant: Kabushiki Kaisha Toshiba, Minato-ku (JP)

(72) Inventor: Katsuhiro SATO, Yokkaichi (JP)

(73) Assignee: Kabushiki Kaisha Toshiba, Minato-ku (JP)

(21) Appl. No.: 15/063,742

(22) Filed: Mar. 8, 2016

(30) Foreign Application Priority Data
Dec. 16, 2015 (JP) 2015-245507

(51) Int. Cl. H01L 21/02; H01L 21/67; B08B 3/10; H01L 21/687

(52) U.S. Cl. CPC H01L 21/02041; H01L 21/68764; H01L 21/68785; H01L 21/67051; H01L 21/67103; H01L 21/67034; B08B 3/10

(57) ABSTRACT

In one embodiment, a substrate processing apparatus includes a substrate retainer and a substrate rotator to retain and rotate a substrate, liquid feeders to supply a cleaning liquid, a rinse liquid and a first coating liquid to a first face of the substrate, a heater to heat the substrate from a second face of the substrate, and a controller to control processing of the substrate. The controller supplies the first coating liquid to the first face while rotating the substrate at a first number of revolution. The controller heats the substrate from the second face while rotating the substrate at a second number of revolution that is different from the first number of revolution after the first coating liquid is supplied, to evaporate a solvent from the first coating liquid to form a coating film containing a solute of the first coating liquid on the first face.

### CROSS REFERENCE TO RELATED APPLICATION

This application is based upon and claims the benefit of priority from the prior Japanese Patent Application No. 2015-245507, filed on Dec. 16, 2015, the entire contents of which are incorporated herein by reference.

### FIELD

Embodiments described herein relate to a substrate processing apparatus and a substrate processing method.

### BACKGROUND

In a spin coating method, a coating liquid is dropped on a substrate while the substrate is rotated, to coat the substrate with the coating liquid under centrifugal force. This makes it possible to form a coating film having high thickness uniformity on the substrate. In general, the thickness of the coating film becomes small when the coating liquid has low viscosity such as 10 cP or less. Therefore, the coating liquid is often adjusted to have high viscosity such as 10 cP or more. However, since an excessive coating liquid on the substrate is shaken off with the centrifugal force in the spin coating method, it is difficult to make the thickness of the coating film large. Moreover, if the start of the heating process to evaporate a solvent from the coating liquid is late in the spin coating method, the coating liquid is caused to be air-dried before the start of the heating process, which makes it impossible to obtain the coating film that is in a desired state.

Meanwhile, sublimation drying is known as a drying method of the substrate after the substrate is cleaned. In the sublimation drying, the substrate is coated with a coating liquid containing a sublimable substance by the spin coating method and a solvent is removed from the coating liquid to form a coating film containing the sublimable substance on the substrate. The coating film is then removed from the substrate by subliming the sublimable substance to dry the substrate. However, the sublimable substance is generally a low molecular substance, and irregularity of the coating film tends to arise when the substrate is coated with the coating liquid containing the low molecular substance. Moreover, the solvent is needed to be removed at low temperature since the sublimable substance is sublimed if the substrate is heated too much for removing the solvent. Therefore, it is desirable in the sublimation drying to use the solvent with low boiling point. However, the solvent with low boiling point generally has low viscosity, which causes difficulty in making the thickness of the coating film large.

### BRIEF DESCRIPTION OF THE DRAWINGS

FIG. 1 is a cross-sectional view schematically illustrating a configuration of a substrate processing apparatus of a first embodiment;

FIGS. 2A to 2F are time charts illustrating operation of the substrate processing apparatus of the first embodiment;

FIG. 3 is a cross-sectional view for explaining the operation of the substrate processing apparatus of the first embodiment;

FIGS. 4A to 4C are cross-sectional views illustrating a substrate processing method of the first embodiment;

FIGS. 5A and 5B are cross-sectional views for comparing the substrate processing method of the first embodiment with that of its comparative example;

FIG. 6 is a cross-sectional view schematically illustrating a configuration of a substrate processing apparatus of a second embodiment;

FIG. 7 is a cross-sectional view schematically illustrating a configuration of a substrate processing apparatus of a third embodiment; and

FIGS. 8A to 8C are plan views schematically illustrating observation results of the coating films of the first and third embodiments.

### DETAILED DESCRIPTION

Embodiments will now be explained with reference to the accompanying drawings.

In one embodiment, a substrate processing apparatus includes a substrate retainer and a substrate rotator configured to retain and rotate a substrate, a cleaning liquid feeder configured to supply a cleaning liquid to a first face of the substrate, a rinse liquid feeder configured to supply a rinse liquid to the first face of the substrate, a first coating liquid feeder configured to supply a first coating liquid to the first face of the substrate, a heater configured to heat the substrate from a second face of the substrate, and a controller including at least one processor and configured to control processing of the substrate. The controller supplies the first coating liquid from the first coating liquid feeder to the first face of the substrate while rotating the substrate at a first number of revolution by the substrate retainer and the substrate rotator. The controller heats the substrate from the second face of the substrate by the heater while rotating the substrate at a second number of revolution that is different from the first number of revolution by the substrate retainer and the substrate rotator after the first coating liquid is supplied to the first face of the substrate, to evaporate a solvent from the first coating liquid to form a coating film containing a solute of the first coating liquid on the first face of the substrate.

### First Embodiment

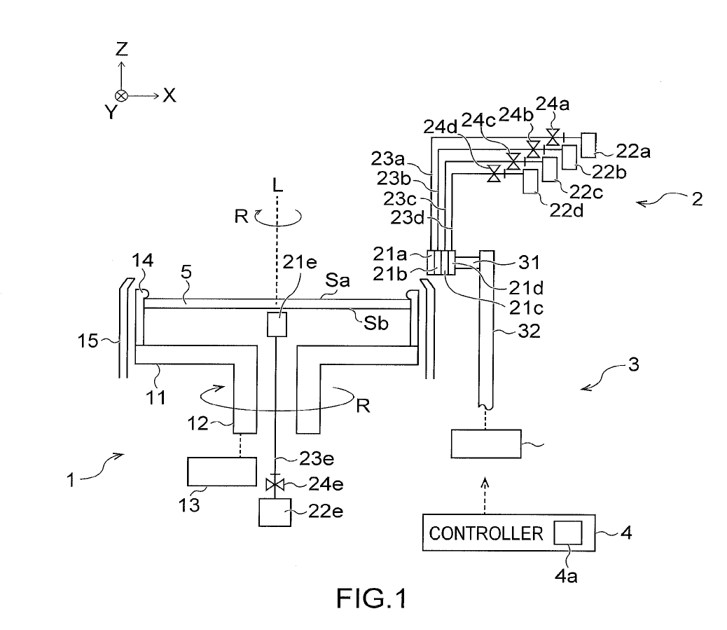

FIG. 1 is a cross-sectional view schematically illustrating a configuration of a substrate processing apparatus of a first embodiment.

The substrate processing apparatus in FIG. 1 includes a substrate retainer and a substrate rotator (hereinafter, referred to as “substrate retainer/rotator”) 1, a fluid feeder 2, a nozzle moving apparatus 3 and a controller 4. The substrate processing apparatus in FIG. 1 is used for cleaning and rinsing a substrate (wafer) 5 and then drying the substrate 5 by sublimation drying. The sublimation drying is a method of drying the substrate 5 that is wet with a cleaning liquid or a rinse liquid. The sublimation drying dries the substrate 5 by replacing the cleaning liquid or the rinse liquid by a solution containing a sublimable substance, separating out the sublimable substance on the substrate 5, and removing the separated sublimable substance by sublimation or degradation.

(1) Substrate Retainer/Rotator 1

The substrate retainer/rotator 1 includes a retainer 11, a rotation shaft 12, a driving device 13, a plurality of chuck pins 14 and a cup 15.

The retainer 11 horizontally retains the substrate 5 with the plurality of chuck pins 14. These chuck pins 14 are arranged at end portions of the retainer 11 so as to be spaced from one another in the circumferential direction. These chuck pins 14 horizontally fix the substrate 5 by gripping the end face of the substrate 5.

An example of the substrate 5 is a workpiece substrate that includes a semiconductor substrate such as a silicon substrate and a workpiece layer on the semiconductor substrate. FIG. 1 illustrates an X-direction and a Y-direction that are parallel to a front face (upper face) Sa and a rear face (lower face) Sb of the substrate 5 and perpendicular to each other, and a Z-direction perpendicular to the front face Sa and the rear face Sb of the substrate 5. The front face Sa is an example of a first face. The rear face Sb is an example of a second face. In the present specification, the +Z-direction is regarded as the upward direction and the −Z-direction is regarded as the downward direction. The −Z-direction may coincide with the direction of gravity or may not coincide with the direction of gravity. The −Z-direction of the present embodiment is substantially parallel to the direction of gravity.

The retainer 11 is fixed to the upper end of the rotation shaft 12 concentrically with the rotation shaft 12 and is rotatable around the rotation shaft 12. The rotation shaft 12 is connected to the driving device 13 such as a motor. The driving device 13 can rotate the retainer 11 and the substrate 5 by rotating the rotation shaft 12. Sign L designates the rotational center of the substrate 5, the retainer 11 and the rotation shaft 12. Sign R designates a rotational direction of the substrate 5, the retainer 11 and the rotation shaft 12.

The cup 15 is disposed around the retainer 11 concentrically with the retainer 11 and has a substantially cylindrical shape. The upper end of the cup 15 is positioned higher than the upper ends of the chuck pins 14. The cup 15 is provided for preventing liquid on the substrate 5 from scattering around due to its rotation. In the present embodiment, a plurality of cups 15 may be arranged around the retainer 11.

(2) Fluid Feeder 2

(2a) Cleaning Liquid

The fluid feeder 2 includes a cleaning liquid nozzle 21a, a cleaning liquid tank 22a, a cleaning liquid supplying tube 23a and a cleaning liquid valve 24a. These components 21a to 24a are an example of a cleaning liquid feeder.

The cleaning liquid nozzle 21a is connected to the cleaning liquid tank 22a storing a cleaning liquid via the cleaning liquid supplying tube 23a. An example of the cleaning liquid is a liquid chemical such as an aqueous solution of hydrogen fluoride (HF), SC1 and SC2. The cleaning liquid supplying tube 23a is provided with the cleaning liquid valve 24a that regulates a flow rate of the cleaning liquid.

The cleaning liquid nozzle 21a ejects the cleaning liquid from the cleaning liquid tank 22a to the front face Sa of the substrate 5. The cleaning liquid nozzle 21a is movable between a waiting position away from the substrate 5 and a supplying position above the front face Sa of the substrate 5. The cleaning liquid is supplied to the front face Sa of the substrate 5 as a cleaning target and is used for cleaning the front face Sa of the substrate 5. The cleaning liquid nozzle 21a may be installed to be fixed above the front face Sa of the substrate 5.

(2b) Rinse Liquid

The fluid feeder 2 further includes a rinse liquid nozzle 21b, a rinse liquid tank 22b, a rinse liquid supplying tube 23b and a rinse liquid valve 24b. These components 21b to 24b are an example of a rinse liquid feeder.

The rinse liquid nozzle 21b is connected to the rinse liquid tank 22b storing a rinse liquid via the rinse liquid supplying tube 23b. An example of the rinse liquid is pure water. The rinse liquid supplying tube 23b is provided with the rinse liquid valve 24b that regulates a flow rate of the rinse liquid.

The rinse liquid nozzle 21b ejects the rinse liquid of the rinse liquid tank 22b to the front face Sa of the substrate 5. The rinse liquid nozzle 21b is movable between the waiting position away from the substrate 5 and the supplying position above the front face Sa of the substrate 5. The rinse liquid is supplied to the front face Sa of the substrate 5 where the cleaning liquid remains and is used for rinsing the front face Sa of the substrate 5. The rinse liquid nozzle 21b may be installed to be fixed above the front face Sa of the substrate 5.

(2c) Pre-Wet Liquid

The fluid feeder 2 further includes a pre-wet liquid nozzle 21c, a pre-wet liquid tank 22c, a pre-wet liquid supplying tube 23c and a pre-wet liquid valve 24c. These components 21c to 24c are an example of a second coating liquid feeder.

The pre-wet liquid nozzle 21c is connected to the pre-wet liquid tank 22c storing a pre-wet liquid via a pre-wet liquid supplying tube 23c. An example of the pre-wet liquid is isopropyl alcohol (IPA). The pre-wet liquid supplying tube 23c is provided with the pre-wet liquid valve 24c that regulates a flow rate of the pre-wet liquid. The pre-wet liquid may be other than IPA as long as it is liquid mixable with the rinse liquid and a sublimable substance solution.

The pre-wet liquid nozzle 21c ejects the pre-wet liquid from the pre-wet liquid tank 22c to the front face Sa of the substrate 5. The pre-wet liquid nozzle 21c is movable between the waiting position away from the substrate 5 and the supplying position above the front face Sa of the substrate 5. The pre-wet liquid is supplied to the front face Sa of the substrate 5 where the rinse liquid remains and is used for replacing the rinse liquid thereby.

The substrate processing apparatus of the present embodiment supplies the pre-wet liquid to the substrate 5 while rotating the substrate 5 at a predetermined number of revolution (third number of revolution). Thereby, it coats the front face Sa of the substrate 5 with the pre-wet liquid under centrifugal force. The pre-wet liquid of the present embodiment is ejected to the center portion of the substrate 5 and spreads from the center portion to the periphery portion of the substrate 5 with the centrifugal force.

(2d) Sublimable Substance Solution

The fluid feeder 2 further includes a sublimable substance solution nozzle 21d, a sublimable substance solution tank 22d, a sublimable substance solution supplying tube 23d and a sublimable substance solution valve 24d. These components 21d to 24d are an example of a first coating liquid feeder.

The sublimable substance solution nozzle 21d is connected to the sublimable substance solution tank 22d storing a sublimable substance solution via the sublimable substance solution supplying tube 23d. A sublimable substance is a substance which is solid at ambient temperature under ambient pressure and has a vapor pressure of 1 kPa or less at ambient temperature. The sublimable substance of the present embodiment has a molecular weight of 500 or less. An example of the sublimable substance solution is a solution of cyclohexanedicarboxylic acid or the like. The sublimable substance solution supplying tube 23d is provided with the sublimable substance solution valve 24d that regulates a flow rate of the sublimable substance solution.

The sublimable substance solution nozzle 21d ejects the sublimable substance solution from the sublimable substance solution tank 22d to the front face Sa of the substrate 5. The sublimable substance solution nozzle 21d is movable between the waiting position away from the substrate 5 and the supplying position above the front face Sa of the substrate 5. The sublimable substance solution is supplied to the front face Sa of the substrate 5 where the pre-wet liquid remains and is used for replacing the pre-wet liquid thereby.

The substrate processing apparatus of the present embodiment supplies the sublimable substance solution to the substrate 5 while rotating the substrate 5 at a predetermined number of revolution (first number of revolution). Thereby, it coats the front face Sa of the substrate 5 with the sublimable substance solution under centrifugal force. The sublimable substance solution of the present embodiment is ejected to the center portion of the substrate 5 and spreads from the center portion to the periphery portion of the substrate 5 with the centrifugal force.

As described above, the substrate processing apparatus of the present embodiment replaces the rinse liquid by the pre-wet liquid and replaces the pre-wet liquid by the sublimable substance solution. Nevertheless, the substrate processing apparatus of the present embodiment may directly replace the rinse liquid by the sublimable substance solution. In this case, the fluid feeder 2 may not have the pre-wet liquid nozzle 21c, the pre-wet liquid tank 22c, the pre-wet liquid supplying tube 23c and the pre-wet liquid valve 24c.

(2e) Heating Liquid

The fluid feeder 2 further includes a heating liquid nozzle 21e, a heating liquid tank 22e, a heating liquid supplying tube 23e and a heating liquid valve 24e. These components 21e to 24e are an example of a heater.

The heating liquid nozzle 21e is connected to the heating liquid tank 22e storing a heating liquid via the heating liquid supplying tube 23e. An example of the heating liquid is water heated at a predetermined temperature. The heating liquid supplying tube 23e is provided with the heating liquid valve 24e that regulates a flow rate of the heating liquid. The temperature of the heating liquid of the present embodiment is configured to be lower than the boiling point of the pre-wet liquid. In the case where the pre-wet liquid is IPA (boiling point: 78° C.), the temperature of the heating liquid is configured, for example, to be 50° C. to 75° C. Moreover, in the case where the rinse liquid is directly replaced by the sublimable substance solution, the temperature of the heating liquid of the present embodiment is configured to be lower than the boiling point of the rinse liquid.

The heating liquid nozzle 21e ejects the heating liquid from the heating liquid tank 22e to the rear face Sb of the substrate 5. By doing so, the substrate 5 can be heated from the rear face Sb. The heating liquid nozzle 21e is disposed below the rear face Sb of the substrate 5. The heating liquid is supplied to the rear face Sb of the substrate 5 in the state where the sublimable substance solution remains on the front face Sa of the substrate 5, and is used for heating the sublimable substance solution. In this way, the solvent can be evaporated from the sublimable substance solution to form a coating film containing the solute (sublimable substance) of the sublimable substance solution on the front face Sa of the substrate 5.

The substrate processing apparatus of the present embodiment supplies the heating liquid to the substrate 5 while rotating the substrate 5 at a predetermined number of revolution (second number of revolution). Thereby, the sublimable substance is separated out in the state of centrifugal force acting. In this way, the coating film that has high thickness uniformity can be formed on the front face Sa of the substrate 5. In the present embodiment, the number of revolution (second number of revolution) of the substrate 5 in supplying the heating liquid is configured to be smaller than the number of revolution (first number of revolution) of the substrate 5 in supplying the sublimable substance solution and the number of revolution (third number of revolution) of the substrate 5 in supplying the pre-wet liquid. In this way, a shaking-off amount of the sublimable substance solution in heating the substrate 5 can be reduced, which enables the thickness of the coating film to be large. The second number of revolution is configured, for example, to be 300 rpm or less.

The heating liquid nozzle 21e may eject the heating liquid to the center portion of the substrate 5 or may eject the heating liquid to the periphery portion of the substrate 5. Moreover, the heating liquid nozzle 21e may eject the heating liquid perpendicularly to the rear face Sb of the substrate 5 or may eject the heating liquid obliquely to the rear face Sb of the substrate 5.

(3) Nozzle Moving Apparatus 3

The nozzle moving apparatus 3 includes an arm part 31, a rotation shaft 32 and a driving device 33.

The cleaning liquid nozzle 21a, the rinse liquid nozzle 21b, the pre-wet liquid nozzle 21c and the sublimable substance solution nozzle 21d are joined to one end of the arm part 31. The rotation shaft 32 is joined to the other end of the arm part 31. The rotation shaft 32 is connected to the driving device 33 such as a motor. The driving device 33 can rotate the arm part 31 by rotating the rotation shaft 32.

With rotation of the arm part 31, the nozzle moving apparatus 3 can move the cleaning liquid nozzle 21a, the rinse liquid nozzle 21b, the pre-wet liquid nozzle 21c and the sublimable substance solution nozzle 21d between the waiting position and the supplying position. The nozzle moving apparatus 3 may simultaneously move these nozzles 21a to 21d or may separately move these nozzles 21a to 21d.

(4) Controller 4

The controller 4 includes at least one processor 4a and controls processing of the substrate 5 by the substrate processing apparatus. For example, the controller 4 controls the number of revolution of the substrate 5 by controlling operation of the driving device 13. Moreover, the controller 4 controls flows and flow rates of the cleaning liquid, the rinse liquid, the pre-wet liquid, the sublimable substance solution and the heating liquid by controlling opening/closing and the degrees of opening of the cleaning liquid valve 24a, the rinse liquid valve 24b, the pre-wet liquid valve 24c, the sublimable substance solution valve 24d and the heating liquid valve 24e. Moreover, the controller 4 controls positions of the cleaning liquid nozzle 21a, the rinse liquid nozzle 21b, the pre-wet liquid nozzle 21c and the sublimable substance solution nozzle 21d by controlling operation of the driving device 33. An example of the processor 4a is a micro processor unit (MPU).

As described above, after the sublimable substance solution is supplied to the front face Sa of the substrate 5, the substrate 5 is heated from the rear face Sb while rotating the substrate 5 at the predetermined number of revolution in the present embodiment. Therefore, according to the present embodiment, the sublimable substance can be separated out in the state of centrifugal force acting, which enables a coating film high in thickness uniformity to be formed on the front face Sa of the substrate 5.

For example, the substrate processing of the present embodiment has the following advantages.

First, the substrate 5 in the present embodiment is heated while rotating the substrate 5. Therefore, convection due to centrifugal force and Marangoni convection due to a temperature difference can be caused to arise in the sublimable substance solution to uniformly concentrate the sublimable substance solution. This makes it possible to suppress irregularity of a coating film from arising and to improve thickness uniformity of the coating film.

Moreover, if the substrate 5 is heated from the front face Sa with a heater or the like, a film is formed on a surface of a liquid film of the sublimable substance solution, which can cause a possibility that the sublimable substance solution is not sufficiently heated. In such a case, the coating film is half-dried, which can cause a possibility that the coating film peels off or a crack arises in the coating film. On the other hand, since the substrate 5 in the present embodiment is heated from the rear face Sb, the coating film can be suppressed form being half-dried.

Moreover, the number of revolution in heating the substrate 5 is configured to be a different value from the numbers of revolution in supplying the pre-wet liquid and the sublimable substance solution in the present embodiment. Specifically, the number of revolution in heating the substrate 5 is configured to be smaller than the numbers of revolution in supplying the pre-wet liquid and the sublimable substance solution. This makes it possible to reduce a shaking-off amount of the sublimable substance solution in heating the substrate 5 and to increase the thickness of the coating film.

As described above, the present embodiment makes it possible to form a coating film on the substrate 5 in an excellent state. For example, the present embodiment makes it possible to form a coating film that is uniform in thickness, large in thickness and sufficiently dried. Moreover, according to the present embodiment, these advantages enable a coating film to be formed in an excellent state even when a coating liquid with low viscosity or a sublimable substance which is a low molecular-weight substance is used.

The substrate processing apparatus of the present embodiment removes the coating film from the substrate 5 by subliming the sublimable substance after the coating film is formed on the front face Sa of the substrate 5. In this way, the sublimation drying of the present embodiment is performed. For example, the substrate processing apparatus of the present embodiment sublimes the sublimable substance by heating the substrate 5 from the rear face Sb with the heating liquid from the heating liquid nozzle 21e. The heating liquid nozzle 21e and the like in this case are an example of a subliming device. The sublimable substance may be sublimed by a device different from the heating liquid nozzle 21e and the like.

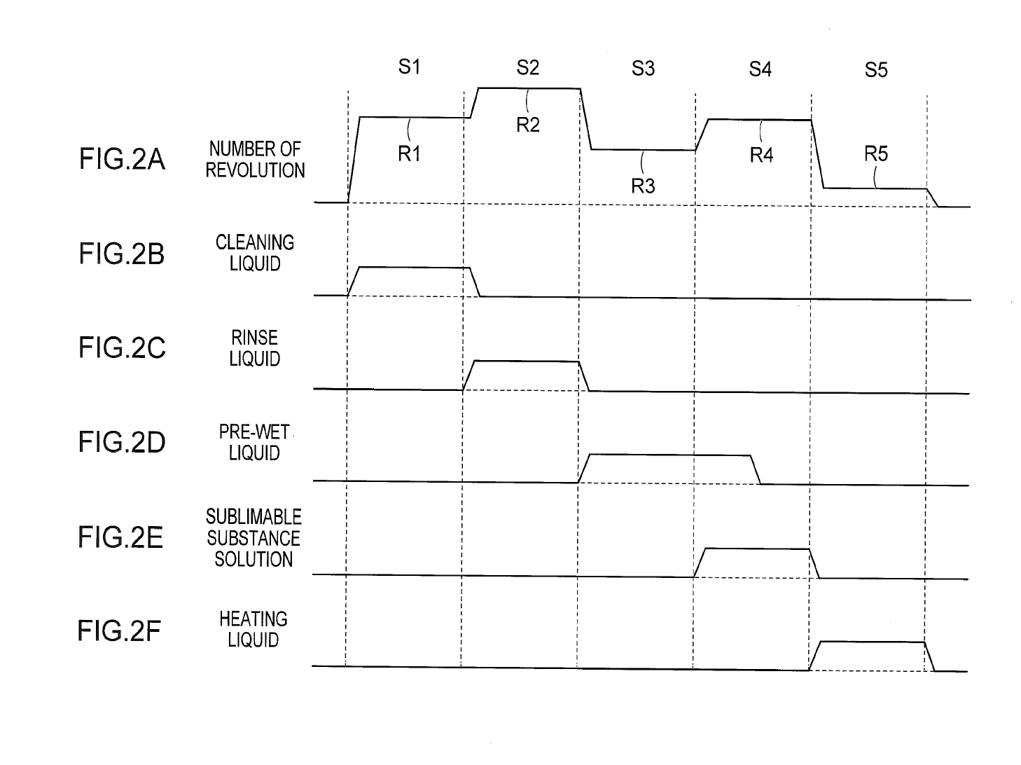

FIGS. 2A to 2F are time charts illustrating operation of the substrate processing apparatus of the first embodiment.

FIG. 2A represents time change of the number of revolution of the substrate 5. FIGS. 2B to 2F represent supply timings of the cleaning liquid, the rinse liquid, the pre-wet liquid, the sublimable substance solution and the heating liquid. The horizontal axis in each of FIGS. 2A to 2F designates time.

First, the cleaning liquid is supplied to the front face Sa of the substrate 5 while rotating the substrate 5 at a number of revolution R1 (step S1). As a result, the cleaning liquid spreads from the center portion to the periphery portion of the substrate 5 and the substrate 5 is cleaned with the cleaning liquid. In step S1, the controller 4 moves the cleaning liquid nozzle 21a to the supplying position and ejects the cleaning liquid from the cleaning liquid nozzle 21a to the substrate 5 while rotating the substrate 5 at the number of revolution R1. As a result, the cleaning liquid sticks to the front face Sa of the substrate 5.

Next, the rinse liquid is supplied to the front face Sa of the substrate 5 while rotating the substrate 5 at a number of revolution R2 (step S2). As a result, the rinse liquid spreads from the center portion to the periphery portion of the substrate 5 and the substrate 5 is rinsed with the rinse liquid. In step S2, the controller 4 moves the rinse liquid nozzle 21b to the supplying position and ejects the rinse liquid from the rinse liquid nozzle 21b to the substrate 5 while rotating the substrate 5 at the number of revolution R2. As a result, the cleaning liquid on the substrate 5 is replaced by the rinse liquid and the rinse liquid sticks to the front face Sa of the substrate 5.

The number of revolution R2 may be the same value as the number of revolution R1 or may be a different value from the number of revolution R1. The number of revolution R2 can be arbitrarily configured, taking account of the replacement efficiency between the cleaning liquid and the rinse liquid. The number of revolution R2 of the present embodiment is configured to be larger than the number of revolution R1.

Next, the pre-wet liquid is supplied to the front face Sa of the substrate 5 while rotating the substrate 5 at a number of revolution R3 (step S3). As a result, the pre-wet liquid spreads from the center portion to the periphery portion of the substrate 5 and the substrate 5 is coated with the pre-wet liquid. In step S3, the controller 4 moves the pre-wet liquid nozzle 21c to the supplying position and ejects the pre-wet liquid from the pre-wet liquid nozzle 21c to the substrate 5 while rotating the substrate 5 at the number of revolution R3. As a result, the rinse liquid on the substrate 5 is replaced by the pre-wet liquid and the pre-wet liquid sticks to the front face Sa of the substrate 5.

The number of revolution R3 may be the same value as the number of revolution R2 or may be a different value from the number of revolution R2. The number of revolution R3 can be arbitrarily configured, taking account of the replacement efficiency between the rinse liquid and the pre-wet liquid. The number of revolution R3 of the present embodiment is configured to be smaller than the numbers of revolution R1 and R2. The number of revolution R3 is an example of the third number of revolution.

Next, the sublimable substance solution is supplied to the front face Sa of the substrate 5 while rotating the substrate 5 at a number of revolution R4 (step S4). As a result, the sublimable substance solution spreads from the center portion to the periphery portion of the substrate 5 and the substrate 5 is coated with the sublimable substance solution. In step S4, the controller 4 moves the sublimable substance solution nozzle 21d to the supplying position and ejects the sublimable substance solution from the sublimable substance solution nozzle 21d to the substrate 5 while rotating the substrate 5 at the number of revolution R4. As a result, the pre-wet liquid on the substrate 5 is replaced by the sublimable substance solution and the sublimable substance solution sticks to the front face Sa of the substrate 5.

The number of revolution R4 may be the same value as the number of revolution R3 or may be a different value from the number of revolution R3. The number of revolution R4 can be arbitrarily configured, taking account of the replacement efficiency between the pre-wet liquid and the sublimable substance solution. The number of revolution R4 of the present embodiment is configured to be equal to the number of revolution R1, smaller than the number of revolution R2 and larger than the number of revolution R3. The number of revolution R4 is an example of the first number of revolution.

The pre-wet liquid of the present embodiment is continued to be ejected even after the number of revolution of the substrate 5 is changed from R3 to R4. Therefore, during a part of the period when the number of revolution is R4, the pre-wet liquid of the present embodiment is continued to be ejected along with the sublimable substance solution.

Next, the heating liquid is supplied to the rear face Sb of the substrate 5 while rotating the substrate 5 at a number of revolution R5 (step S5). As a result, the solvent is evaporated from the sublimable substance solution and the coating film containing the sublimable substance is formed on the front face Sa of the substrate 5. In step S5, the controller 4 ejects the heating liquid from the heating liquid nozzle 21e to the substrate 5 while rotating the substrate 5 at the number of revolution R5. As a result, the sublimable substance solution on the substrate 5 is heated and the sublimable substance is separated out on the substrate 5.

The number of revolution R5 of the present embodiment is configured to be a different value from the numbers of revolution R3 and R4. Specifically, the number of revolution R5 of the present embodiment is configured to be smaller than the numbers of revolution R1 to R4. The number of revolution R5 is, for example, 300 rpm or less. In this way, the sublimable substance solution on the substrate 5 can be sufficiently suppressed from scattering around due to the rotation. The number of revolution R5 is an example of the second number of revolution.

The heating liquid of the present embodiment is desirably started to be ejected while the sublimable substance solution is being ejected. Namely, an ejecting period of the heating liquid is desirably overlapped with an ejecting period of the sublimable substance solution. In this way, the sublimable substance can be prevented from being separated out before the substrate 5 has been sufficiently heated. As above, the heating liquid of the present embodiment may be started to be supplied after all of the sublimable substance solution has been supplied or may be started to be supplied after a part of the sublimable substance solution has been supplied.

The temperature of the heating liquid in step S5 may take any value as long as the solvent can be evaporated from the sublimable substance solution. It should be noted that the temperature of the heating liquid is desirable to be lower than the melting point of the sublimable substance. The reason is that if the sublimable substance melts during the coating film being formed, a pattern formed on the front face Sa of the substrate 5 may suffer its collapse due to surface tension of the sublimable substance or the like. Moreover, the temperature of the heating liquid is desirable to be lower than the boiling point of the solvent in the sublimable substance solution. The reason is that thickness uniformity of the coating film is suppressed from deteriorating due to boiling of the solvent during formation of the coating film. Moreover, the temperature of the heating liquid is desirable to be not less than ambient temperature.

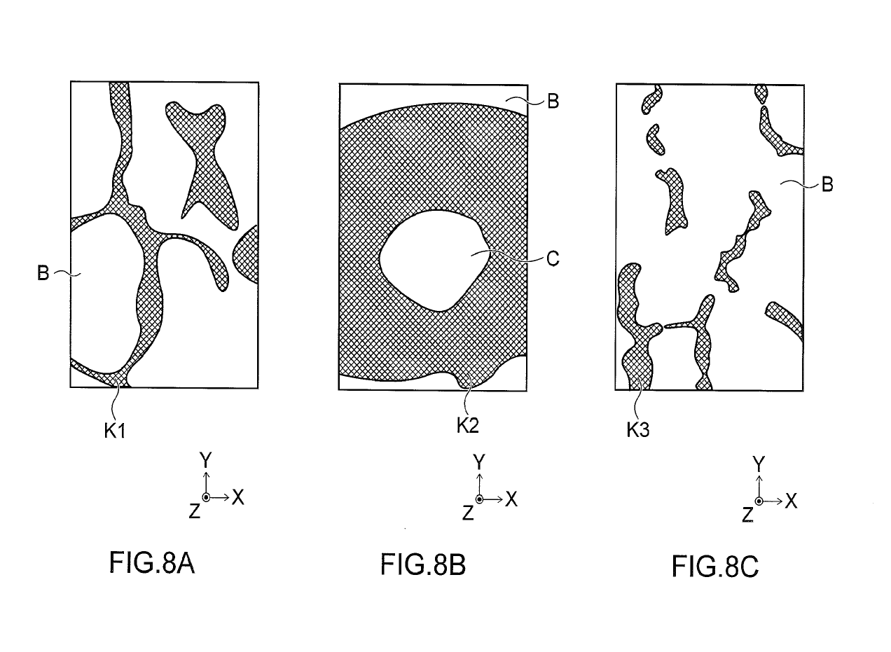

A first experiment in which the coating film was formed by performing all of steps S1 to S5 and a second experiment in which the coating film was formed by performing steps S1 to S5 not using the heating liquid were performed. The viscosity of the sublimable substance solution was configured to be 2.4 cP. The temperature of the heating liquid was configured to be 60° C. Under such conditions, the coating film in the second experiment was observed with an optical microscope. As a result, as illustrated in FIGS. 8A and 8B, Bénard cells B were formed. A region K1 in which the coating film was not present in the boundary of the Bénard cells B and a region K2 in which the coating film was not present around a core C arose, which caused irregularity of the coating film. FIGS. 8A to 8C are plan views schematically illustrating the observation results of the coating films of the first and third embodiments. Meanwhile, the coating film in the first experiment was observed with an optical microscope. As a result, the coating film was formed on the whole surface of the front face Sa of the substrate 5 and irregularity of the coating film did not almost arise.

The substrate processing apparatus of the present embodiment may perform baking processing on the substrate 5 after step S5. By doing so, a solvent little remaining in the coating film can be removed. The baking processing is performed, for example, by heating under ambient pressure in the state where the substrate 5 is caused to stand still without rotation. Meanwhile, such a solvent may be removed by drying the substrate 5 under reduced pressure.

The substrate 5 of the present embodiment may include, for example, a two-dimensional or three-dimensional NAND flash memory or a micro electro mechanical systems (MEMS) structure. The substrate processing of the present embodiment is desirably applied to sublimation drying of the substrate 5 that includes roughness patterns on the front face Sa. According to the present embodiment, in the case where sublimation drying is applied to the substrate 5 including roughness patterns high in aspect ratio, these roughness patterns can be covered with a thick coating film, which enables the sublimation drying of the substrate 5 to be properly performed. This makes it possible to improve yield of semiconductor devices produced from this substrate 5.

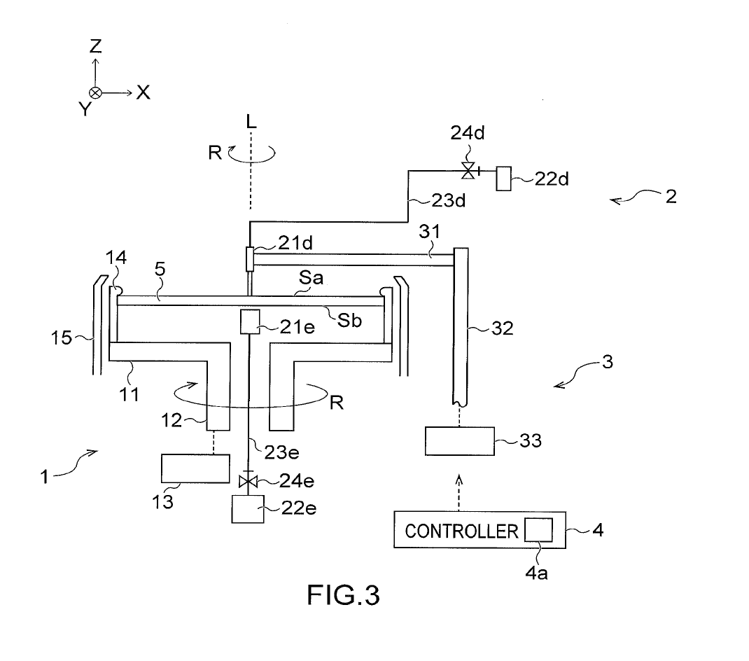

FIG. 3 is a cross-sectional view for explaining the operation of the substrate processing apparatus of the first embodiment.

FIG. 3 illustrates the substrate processing apparatus which is performing step S4. In step S4, the controller 4 moves the sublimable substance solution nozzle 21d to the supplying position and ejects the sublimable substance solution from the sublimable substance solution nozzle 21d to the substrate 5 while rotating the substrate 5 at the number of revolution R4. The supplying position in FIG. 3 is positioned on the rotational center axis L of the substrate 5.

The controller 4 of the present embodiment moves the cleaning liquid nozzle 21a, the rinse liquid nozzle 21b and the pre-wet liquid nozzle 21c to the supplying positions also in steps S1 to S3, similarly to step S4. The supplying positions in these cases may be the same position as the position in FIG. 3 or may be different from the position in FIG. 3.

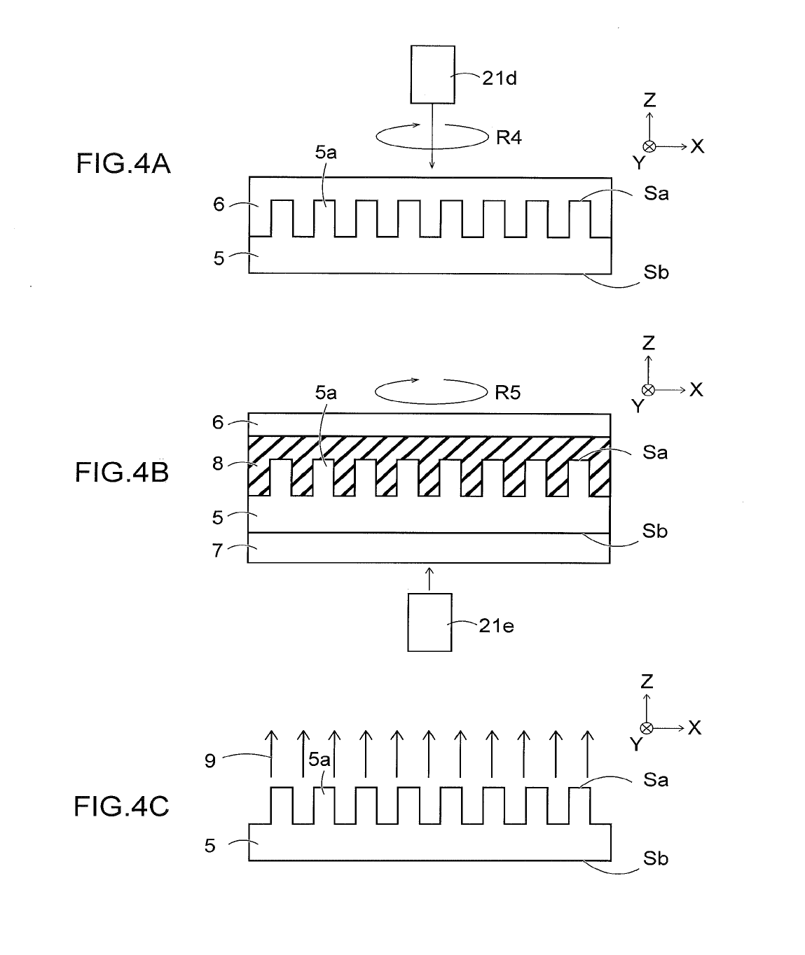

FIGS. 4A to 4C are cross-sectional views illustrating a substrate processing method of the first embodiment. The substrate processing method is performed by the substrate processing apparatus in FIG. 1.

First, after steps S1 to S3 are performed, a sublimable substance solution 6 is supplied to the front face Sa of the substrate 5 while rotating the substrate 5 at the number of revolution R4 (FIG. 4A). As a result, the substrate 5 is coated with the sublimable substance solution 6 and patterns 5a provided in the substrate 5 are covered with the sublimable substance solution 6. An example of the pattern 5a of the substrate 5 is a memory structure for a three-dimensional memory.

Next, a heating liquid 7 is supplied to the rear face Sb of the substrate 5 while rotating the substrate 5 at the number of revolution R5 different from the number of revolution R4 (FIG. 4B). As a result, the solvent is evaporated from the sublimable substance solution 6 and a coating film 8 containing the sublimable substance is formed on the front face Sa of the substrate 5. In the present embodiment, the patterns 5a of the substrate 5 are completely covered with the coating film 8.

Next, the sublimable substance is sublimed, and thereby, the coating film 8 is removed from the substrate 5 (FIG. 4C). In this way, the sublimation drying of the present embodiment is performed. Sign 9 designates a product generated by the sublimation. The sublimable substance may be sublimed by heating with the heating liquid from the heating liquid nozzle 21e or may be sublimed by another method.

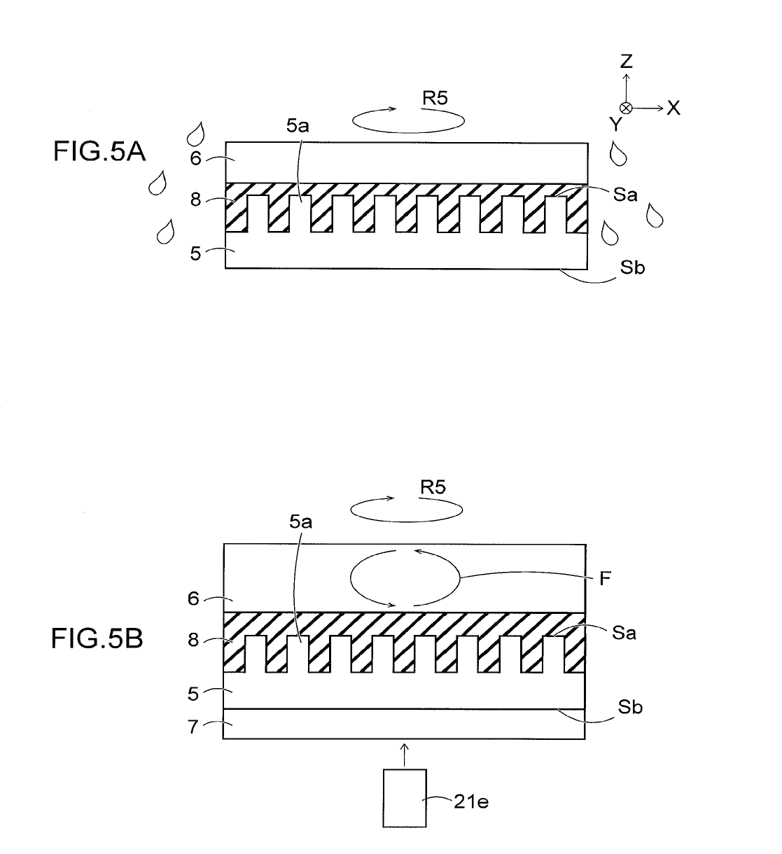

FIGS. 5A and 5B are cross-sectional views for comparing the substrate processing method of the first embodiment with that of its comparative example.

FIG. 5A illustrates a substrate processing method of the comparative example. In FIG. 5A, the coating film 8 is formed by performing step S5 not using the heating liquid 7. In this case, the number of revolution R5 is configured to be a high speed and a sublimable substance solution 6 that is excessive on the substrate 5 is shaken off with centrifugal force. Therefore, the thickness of the coating film 8 results in being small. As a result, there can be possibilities of shortage of the coating film 8 and that the patterns 5a of the substrate 5 are not completely covered with the coating film 8.

FIG. 5B illustrates the substrate processing method of the first embodiment. In FIG. 5B, the coating film 8 is formed by performing step S5 using the heating liquid 7. In this case, the number of revolution R5 can be configured to be a low speed, and thereby, the shaking-off amount of the sublimable substance solution 6 can be reduced. In this way, the thickness of the coating film 8 can be made sufficiently large, which enables sublimation drying to be properly performed. Furthermore, due to convection F in the sublimable substance solution 6, thickness uniformity of the coating film 8 can be improved.

As described above, the sublimable substance solution in the present embodiment is supplied to the front face Sa of the substrate 5 while rotating the substrate 5 at the first number of revolution R4. Furthermore, the substrate 5 in the present embodiment is heated from the rear face Sb while rotating the substrate 5 at the second number of revolution R5, to evaporate the solvent from the sublimable substance solution to form the coating film containing the sublimable substance on the front face Sa of the substrate 5. Therefore, the present embodiment makes it possible to form a coating film on the substrate 5 in an excellent state.

### Second Embodiment

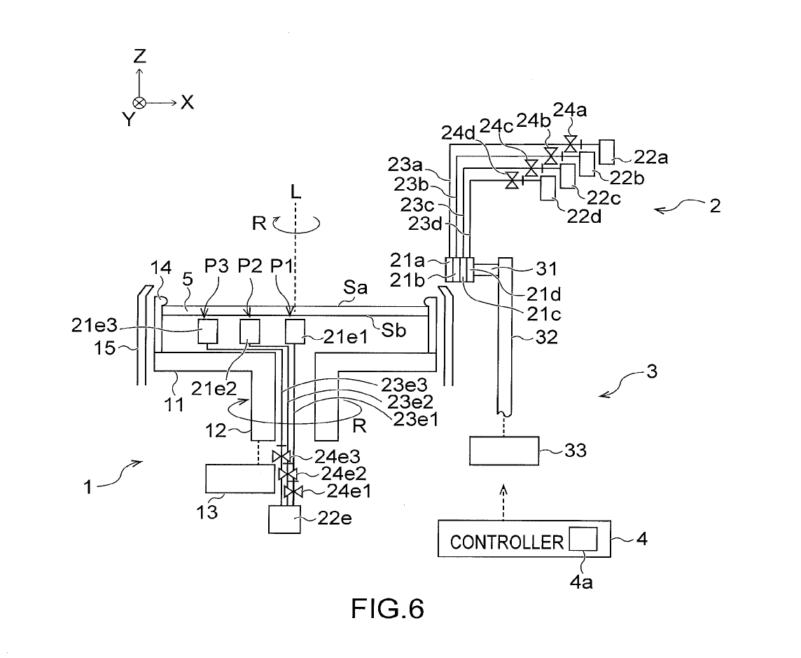

FIG. 6 is a cross-sectional view schematically illustrating a configuration of a substrate processing apparatus of a second embodiment. In FIG. 6, components that are same as or similar to the components illustrated in FIGS. 1 to 5B are given the same signs, and their duplicated description is omitted.

The substrate processing apparatus in FIG. 6 includes first to third heating liquid nozzles 21e1 to 21e3 as the heating liquid nozzle 21e, includes first to third heating liquid supplying tubes 23e1 to 23e3 as the heating liquid supplying tube 23e, and includes first to third heating liquid valves 24e1 to 24e3 as the heating liquid valve 24e. The first to third heating liquid nozzles 21e1 to 21e3 are an example of a plurality of nozzles. Any two of the first to third heating liquid nozzles 21e1 to 21e3 are examples of first and second nozzles.

The first to third heating liquid nozzles 21e1 to 21e3 are connected to the heating liquid tank 22e storing the heating liquid via the first to third heating liquid supplying tubes 23e to 23e3, respectively. The first to third heating liquid supplying tubes 23e1 to 23e3 are provided with the first to third heating liquid valves 24e1 to 24e3 that regulate flow rates of the heating liquid, respectively.

The first to third heating liquid nozzles 21e1 to 21e3 eject the heating liquid from the heating liquid tank 22e to first to third ejecting places P1 to P3 on the rear face Sb of the substrate 5, respectively. Distances between the first to third ejecting places P1 to P3 and the rotational center L are different from one another. Specifically, the first ejecting place P1 is positioned in the center portion, of the substrate 5, close to the rotational center L. The third ejecting place P3 is positioned in the periphery portion, of the substrate 5, distant from the rotational center L. The second ejecting place P2 is positioned between the first ejecting place P1 and the third ejecting place P3.

The heating liquid from the first heating liquid nozzle 21e1, the heating liquid from the second heating liquid nozzle 21e2 and the heating liquid from the third heating liquid nozzle 21e3 may have the same temperature or may have different temperatures. In the present embodiment, the temperature of the heating liquid from a nozzle is configured to be higher as the distance between that nozzle and the rotational center L is larger. Therefore, the temperature of the heating liquid from the second heating liquid nozzle 21e2 is configured to be higher than the temperature of the heating liquid from the first heating liquid nozzle 21e1. Moreover, the temperature of the heating liquid from the third heating liquid nozzle 21e3 is configured to be higher than the temperature of the heating liquid from the second heating liquid nozzle 21e2.

The substrate processing apparatus of the present embodiment may include first to Nth heating liquid nozzles 21e1 to 21eN as the heating liquid nozzle 21e (N is an integer not less than 2). The value of N may be other than 3. According to the present embodiment, the substrate 5 can be efficiently heated by heating the substrate 5 from the rear face Sb with the heating liquids from the first to Nth heating liquid nozzles 21e1 to 21eN.

The substrate processing apparatus of the present embodiment supplies the heating liquids from the first to third heating liquid nozzles 21e1 to 21e3 to the substrate 5 while rotating the substrate 5 at the predetermined number of revolution (second number of revolution). By doing so, the sublimable substance can be separated out in the state of centrifugal force acting and the coating film high in thickness uniformity can be formed on the front face Sa of the substrate 5. In this stage, it is desirable that the heating liquid from the second heating liquid nozzle 21e2 is configured to be at a higher temperature than the heating liquid from the first heating liquid nozzle 21e1, and the heating liquid from the third heating liquid nozzle 21e3 is configured to be at a higher temperature than the heating liquid from the second heating liquid nozzle 21e2. This makes it possible to heat the substrate 5 such that the temperature of the periphery portion of the substrate 5 is higher than the temperature of the center portion of the substrate 5. The second number of revolution is, for example, 150 rpm or less.

The sublimable substance solution in the periphery portion undergoes stronger centrifugal force than the sublimable substance solution in the center portion. Therefore, it spreads at a higher speed than the sublimable substance solution in the center portion. Therefore, the thickness of the sublimable substance solution in the periphery portion tends to be smaller than that in the center portion. As a result, the thickness of the coating film in the periphery portion also tends to be smaller than that in the center portion. Then, it can be considered that the heating liquid from the nozzle 21e2 is configured to be at a higher temperature than the heating liquid from the nozzle 21e1, and the heating liquid from the nozzle 21e3 is configured to be at a higher temperature than the heating liquid from the nozzle 21e2. This makes it possible to easily evaporate the solvent from the sublimable substance solution in the periphery portion, and to suppress the coating film in the periphery portion from becoming thin.

The substrate processing of the present embodiment can be performed, for example, in accordance with steps S1 to S5 in FIGS. 2A to 2F, wherein the numbers of revolution R1, R2, R3, R4 and R5 are configured, for example, to be 1000 rpm, 800 rpm, 500 rpm, 500 rpm and 100 rpm, respectively. In the case where the pre-wet liquid is IPA, the number of revolution R5 is desirably configured to be 30 to 150 rpm. The temperature of the heating liquid is desirably configured to be 30 to 70° C. After the heating liquid in step S5 is stopped, the substrate 5 may be rotated at a high speed to shake off the heating liquid from the substrate 5. The number of revolution of the substrate 5 in this case is, for example, 1000 rpm. These numbers of revolution R1 to R5 may be applied to the first embodiment.

As described above, the temperature of the substrate 5 is controlled in accordance with the distance of the substrate 5 from the rotational center L in the present embodiment. Therefore, this makes it possible to control irregularity of the coating film more effectively.

### Third Embodiment

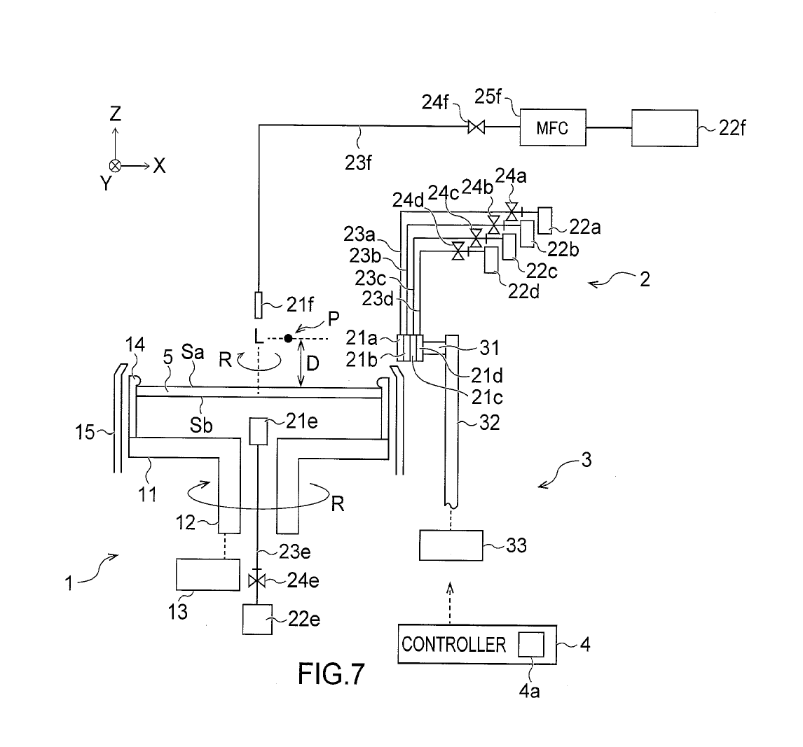

FIG. 7 is a cross-sectional view schematically illustrating a configuration of a substrate processing apparatus of a third embodiment. In FIG. 7, components that are same or similar to the components illustrated in FIGS. 1 to 6 are given the same signs, and their duplicated description is omitted.

The substrate processing apparatus in FIG. 7 includes a gas nozzle 21f, a gas tank 22f, a gas supplying tube 23f, a gas valve 24f and a mass flow controller (MFC) 25f in addition to the components illustrated in FIG. 1. These components 21f to 25f are an example of a gas feeder.

The gas nozzle 21f is connected to the gas tank 22f storing a gas via the gas supplying tube 23f. An example of the gas is an inert gas which does not react with the sublimable substance solution and, for example, a rare gas or a nitrogen (N₂) gas. The gas supplying tube 23f is provided with the gas valve 24f and the MFC 25f that regulate a flow rate of the gas. Operation of these components 21f to 25f is controlled by the controller 4.

The gas of the present embodiment is used for controlling a vapor concentration above the substrate 5. The vapor is generated from the solvent of the sublimable substance solution on the substrate 5. The gas of the present embodiment may be supplied in any method as long as the vapor concentration can be controlled. For example, the gas nozzle 21f may be replaced by a fan filter unit (FFU). In this case, the MFC 25f may be replaced by monitoring the output of the fan of the FFU.

The gas nozzle 21f ejects the gas from the gas tank 22f to the side of the front face Sa of the substrate 5. The gas nozzle 21f is movable between a waiting position away from the substrate 5 and a supplying position above the front face Sa of the substrate 5. The supplying position of the present embodiment is positioned on the rotational center axis L of the substrate 5. The gas of the present embodiment is supplied during the substrate 5 being heated while being rotated in step S5.

In the present embodiment, a wind speed on the side of the front face Sa of the substrate 5 is controlled with the gas from the gas nozzle 21f. The reason is that the solvent is made easy to be evaporated from the sublimable substance solution on the substrate 5 by reducing the vapor concentration above the substrate 5.

Point P is positioned at a height away from the front face Sa of the substrate 5 by a distance D, and is positioned near the rotational center axis L of the substrate 5. In the present embodiment, the gas is supplied from the gas nozzle 21f such that the wind speed at point P in the case where the distance D is 20 mm is less than 1.0 m/s. This makes it possible to suppress the solvent vapor concentration of the sublimable substance solution above the substrate 5 to be lower than a predetermined concentration.

For example, when the wind speed at point P in the case where the distance D is 20 mm is configured to be less than 1.0 m/s, the vapor concentration near the front face Sa of the substrate 5 can be suppressed to be less than 1200 ppm. The wind speed at point P in the case where the distance D is 20 mm is configured, for example, to be 0.3 to 1.0 m/s.

A first experiment in which the coating film was formed by performing step S5 using the heating liquid, a second experiment in which the coating film was formed by performing step S5 not using the heating liquid, and a third experiment in which the coating film was formed by performing step S5 using the gas from the gas nozzle 21f were performed. The viscosity of the sublimable substance solution was configured to be 2.4 cP. The temperature of the heating liquid was configured to be 60° C. Under such conditions, the coating films in the first to third experiments were observed with an optical microscope. As a result, as illustrated in FIG. 8C, a region K3 in which the coating film was not present in the boundary of the Bénard cells B was more reduced in the third experiment than in the first experiment. Irregularity of the coating film in the third experiment was more improved than in the first experiment. For example, when the wind speed at point P in the case where the distance D was 20 mm was configured to be 0.5 m/s, the vapor concentration near the front face Sa of the substrate 5 became 760 ppm and the dimension of the Bénard cells B was able to be suppressed not more than 2 μm.

However, when the wind speed on the side of the front face Sa of the substrate 5 is made too fast, there can be a case where the evaporation amount of the solvent from the sublimable substance solution becomes too much. In such a case, the vapor concentration near the front face Sa of the substrate 5 becomes high conversely, which increases the dimension of the Bénard cells B. For example, when the wind speed at point P in the case where the distance D was 20 mm was configured to be 1.0 m/s, the vapor concentration near the front face Sa of the substrate 5 became 2050 ppm and the dimension of the Bénard cells B became up to 10 μm or more. Furthermore, the gas from the gas nozzle 21f was in direct contact with the sublimable substance solution on the substrate 5, and irregularity of the coating film in another mode arose. Namely, irregularity of the coating film due to air-drying arose. Therefore, in the present embodiment, the wind speed at point P in the case where the distance D is 20 mm is configured to be less than 1.0 m/s such that the wind speed on the side of the front face Sa of the substrate 5 is not too fast.

As described above, the wind speed on the side of the front face Sa of the substrate 5 is controlled with the gas from the gas nozzle 21f in the present embodiment. Therefore, the present embodiment makes it possible to suppress irregularity of the coating film more effectively.

While certain embodiments have been described, these embodiments have been presented by way of example only, and are not intended to limit the scope of the inventions. Indeed, the novel apparatuses and methods described herein may be embodied in a variety of other forms; furthermore, various omissions, substitutions and changes in the form of the apparatuses and methods described herein may be made without departing from the spirit of the inventions. The accompanying claims and their equivalents are intended to cover such forms or modifications as would fall within the scope and spirit of the inventions.

1. A substrate processing apparatus comprising:
a substrate retainer and a substrate rotator configured to retain and rotate a substrate;
a cleaning liquid feeder configured to supply a cleaning liquid to a first face of the substrate;
a rinse liquid feeder configured to supply a rinse liquid to the first face of the substrate;
a first coating liquid feeder configured to supply a first coating liquid to the first face of the substrate;
a heater configured to heat the substrate from a second face of the substrate; and
a controller including at least one processor and configured to control processing of the substrate,
wherein the controller supplies the first coating liquid from the first coating liquid feeder to the first face of the substrate while rotating the substrate at a first number of revolution by the substrate retainer and the substrate rotator, and
wherein the controller heats the substrate from the second face of the substrate by the heater while rotating the substrate at a second number of revolution that is different from the first number of revolution by the substrate retainer and the substrate rotator after the first coating liquid is supplied to the first face of the substrate, to evaporate a solvent from the first coating liquid to form a coating film containing a solute of the first coating liquid on the first face of the substrate.

2. The apparatus of claim 1, wherein the solute is solid at ambient temperature under ambient pressure and has a molecular weight of 500 or less.

3. The apparatus of claim 2, further comprising a subliming device configured to remove the coating film from the substrate by subliming the solute after the coating film is formed.

4. The apparatus of claim 1, further comprising a second coating liquid feeder configured to supply a second coating liquid to the first face of the substrate,
wherein the controller supplies the second coating liquid from the second coating liquid feeder to the first face of the substrate while rotating the substrate at a third number of revolution that is different from the second number of revolution, before the first coating liquid is supplied to the first face of the substrate while the substrate is rotated at the first number of revolution.

5. The apparatus of claim 1, wherein the heater comprises a plurality of nozzles configured to supply heating liquids with different temperatures to a plurality of places on the second face of the substrate.

6. The apparatus of claim 1, wherein the heater comprises:
a first nozzle configured to supply a heating liquid with a first temperature to a first place on the second face of the substrate, and
a second nozzle configured to supply a heating liquid with a second temperature that is higher than the first temperature to a second place on the second face of the substrate, and
a distance between the second place and a rotational center of the substrate is larger than a distance between the first place and the rotational center of the substrate.

7. The apparatus of claim 1, further comprising a gas feeder configured to supply a gas on a side of the first face of the substrate,
wherein the controller controls a wind speed on the side of the first face of the substrate with the gas from the gas feeder, when the substrate is heated while the substrate is rotated at the second number of revolution.

8. A substrate processing method comprising:
cleaning a first face of a substrate with a cleaning liquid;
rinsing the first face of the substrate with a rinse liquid;
supplying a first coating liquid to the first face of the substrate while rotating the substrate at a first number of revolution; and
heating the substrate from a second face of the substrate while rotating the substrate at a second number of revolution that is different from the first number of revolution after the first coating liquid is supplied to the first face of the substrate, to evaporate a solvent from the first coating liquid to form a coating film containing a solute of the first coating liquid on the first face of the substrate.

9. The method of claim 8, wherein the solute is solid at ambient temperature under ambient pressure and has a molecular weight of 500 or less.

10. The method of claim 9, further comprising removing the coating film from the substrate by subliming the solute after the coating film is formed.

11. The method of claim 9, wherein the substrate is heated with a heating liquid with a lower temperature than a melting point of the solute while the substrate is rotated at the second number of revolution.

12. The method of claim 8, wherein the substrate is heated with a heating liquid with a lower temperature than a boiling point of the solvent while the substrate is rotated at the second number of revolution.

13. The method of claim 8, wherein the second number of revolution is smaller than the first number of revolution.

14. The method of claim 8, wherein the second number of revolution is 300 rpm or less.

15. The method of claim 8, further comprising supplying a second coating liquid to the first face of the substrate while rotating the substrate at a third number of revolution that is different from the second number of revolution, before the first coating liquid is supplied to the first face of the substrate while the substrate is rotated at the first number of revolution.

16. The method of claim 15, wherein the second coating liquid contains alcohol.

17. The method of claim 15, wherein the second number of revolution is smaller than the third number of revolution.

18. The method of claim 8, wherein the substrate is heated such that a temperature in a periphery portion of the substrate is higher than a temperature in a center portion of the substrate, while the substrate is rotated at the second number of revolution.

19. The method of claim 8, further comprising supplying a gas on a side of the first face of the substrate to control a wind speed on the side of the first face of the substrate, when the substrate is heated while the substrate is rotated at the second number of revolution.

20. The method of claim 19, wherein the gas is supplied such that the wind speed at a position away from the first face of the substrate by 20 mm is less than 1.0 m/s.
